(19) United States
(12) Patent Application Publication
(10) Pub. No.: US 2011/0048485 A1
(43) Pub. Date: Mar. 3, 2011

(54) Integrated battery management system for vehicles

(76) Inventors: Lonnie Calvin Goff, Tempe, AZ (US); Mark Edmond Eidson, Tempe, AZ (US); Mick Conley, Thousand Oaks, CA (US)

(21) Appl. No.: 12/584,252

(22) Filed: Sep. 2, 2009

(51) Int. Cl. H01L 35/28

(52) U.S. Cl. 136/203

(57) ABSTRACT

A Peltier device manufactured into the surface of a battery cell

### CROSS REFERENCE TO RELATED APPLICATIONS

This application is related to the following applications that have all been filed by the present inventors. Ser. No. 12/321,310 filed on Jan. 15, 2009 and entitled “Embedded Monitoring System for Batteries”. Ser. No. 12/380,236 filed on Feb. 25, 2009 and entitled “Embedded Microprocessor System for Vehicular Batteries”. And Ser. No. 12/454,454 filed on May 18, 2009 and entitled “Embedded Algorithms for Vehicular Batteries”.

### FEDERALLY SPONSORED RESEARCH OR DEVELOPMENT

Not Applicable

### SEQUENCE LISTING, TABLE OR COMPUTER PROGRAM LISTING ON CD

Not Applicable

### BACKGROUND OF THE INVENTION

1. Field of Invention

The present invention relates to vehicular battery technology and the field of computers. In particular it relates to how changes can be made to battery cell technology and to battery management systems in order to reduce the cost of electric and hybrid vehicles, to improve battery cell efficiency and to reduce the likelihood of physical damage to the battery management system.

2. Prior Art

Modern electric and hybrid vehicles that derive their motive power from lithium-based or nickel-based batteries require sophisticated battery management systems to insure the safety of the passengers and to prolong battery life. These batteries can catch fire, rupture or explode if not properly maintained.

The new Chevrolet Volt hybrid vehicle contains over 200 lithium-ion cells in its battery pack. Each cell's voltage is monitored. Temperature sensors and current sensors are strategically placed throughout the battery pack. All of these sensors plus the voltage taps for the individual cells reside outside the lithium-ion cells. The battery management system that is wired to these sensors is, itself, also external to the lithium-ion cells.

One of the key functions performed by the battery management system is cell-balancing. Cell-balancing is typically required when lithium-based or nickel-based cells are connected in series. The weakest cell in the series governs the performance of the battery. Cell-balancing is designed to reduce the stress on the weaker battery cells and is performed by shunting current around individual battery cells. For example, during a charge cycle, those cells approaching full charge get a portion of their current shunted around the cell to slow down their charge rate while can be driven to the same state of charge.

The shunted current must be driven through resistive, capacitive or inductive loads. Through complex and often proprietary schemes the energy shunted through capacitive and inductive loads can be transferred to the weaker cells in the battery pack. This is the approach used by the Chevy Volt. The downside to this approach is that active and passive network and control components must reside outside the cell. On the other hand, resistive loads as used in the Toyota Prius result in the generation of wasted heat that is, in itself, detrimental to maintaining the ideal operating temperature of a cell. Neither the Chevy Volt nor the Toyota Prius approach is ideal.

### BRIEF SUMMARY OF THE INVENTION

The present invention makes use of computer systems that are described by the present inventors in application Ser. No. 12/321,310 filed on Jan. 15, 2009 and entitled “Embedded Monitoring System for Batteries” and in application Ser. No. 12/380,236 filed on Feb. 25, 2009 and entitled “Embedded Microprocessor System for Vehicular Batteries”. These computer systems are designed to reside inside the battery.

The present invention makes use of embedded computer systems to implement a battery management system for multi-cell batteries that require cell-balancing. The notion of using computer systems to manage lithium-based and nickel-based batteries is neither new nor unexpected and is required to insure passenger safety and to prolong battery life. General Motors is using such a system with its new Chevy Volt hybrid vehicle. Bosch is doing the same for the new BMW hybrid.

The present invention makes uses of a Peltier device for controlling the temperature of individual cells. To use a Peltier device in the proximity of a battery cell is neither new nor unexpected. U.S. Pat. No. 7,061,208 by Nishihata; Hideo, et al. suggests such an arrangement.

What is missing in the prior art is the synergy that results by manufacturing a Peltier device into the surface of a battery cell, installing the battery management system inside the cell and supplying the normally wasted power, which is a byproduct of cell-balancing, to the Peltier device using no external connections. The polarity of the wasted energy applied to the Peltier device, under the control of the battery management system, causes the battery cell to be either heated or cooled. By regulating the temperature of the cell with wasted cell-balancing energy the efficiency of the system, in general, and the battery cell, in particular, is improved. By placing the battery management system inside the cell, the temperature of the cell is more accurately monitored, the battery management system's active components become safely entombed inside the cell's wall and there are no external connections to the Peltier device. The only external remnant of the battery management system is the wires used for inter-cellular and inter-battery communication. If a wireless communication scheme is adopted even these wires go away and the battery management system disappears from sight.

Manufacturing costs are driven down because the battery management system is integrated within the cell, cell efficiency is driven up because the Peltier device moderates the cell's temperature with free energy and the physical integrity of the system is improved since the battery management system safely resides inside the cell's walls.

### BRIEF DESCRIPTION OF THE DRAWINGS

FIG. 1 is a block diagram of a computer-based system shown embedded inside a battery cell. A Peltier device is shown manufactured into the surface of one side of the cell. This computer system includes means for measuring the voltage, current and temperature inside the cell (not shown). The computer system includes algorithms that perform cell-balancing and includes a means for switching power to the Peltier device.

FIG. 1A is a flow chart illustrating the steps taken by the computer system of FIG. 1 to supply power to the Peltier device using the excess energy made available from cell-balancing.

FIG. 2 is a block diagram of a computer-based system shown embedded inside a battery cell. A Peltier device is shown manufactured into the surface of one side of the cell. This computer system includes means for measuring the voltage, current and temperature of the cell. The computer system includes facilities for communication across a wireless channel. The computer system includes a means for controlling the polarity of the voltage applied to the Peltier device.

FIG. 2A is a flow chart illustrating the steps taken by the computer system of FIG. 2 to supply power to the Peltier device using the excess energy made available from cell-balancing.

### DETAILED DESCRIPTION OF THE INVENTION

The following descriptions are provided to enable any person skilled in the art to make and use the invention and are provided in the context of two particular embodiments. Various modifications to these embodiments are possible and the generic principles defined herein may be applied to these and other embodiments without departing from the spirit and scope of the invention. Both embodiments describe cell-balancing during the charge cycle but the means described herein also apply to the discharge cycle. Special notification is made with regard to battery technology. The generic principles described herein apply to any battery cell type that makes use of cell-balancing. It is not limited to lithium-based or nickel-based battery cells. Thus the invention is not intended to be limited to the embodiments shown but is to be accorded the widest scope consistent with the principles, features and teachings disclosed herein.

In accordance with one embodiment, the present invention makes use of a computer system that resides inside a battery cell. A Peltier device is manufactured into the surface of one side of the cell's casework. The computer system includes temperature, current and voltage sensors (not shown). The computer system's central processing unit also has a means to measure time and includes facilities for storing data. The computer system's non-volatile memory includes algorithms that perform cell-balancing by shunting power to the Peltier device when the current passing through the power of the cell is to be mitigated.

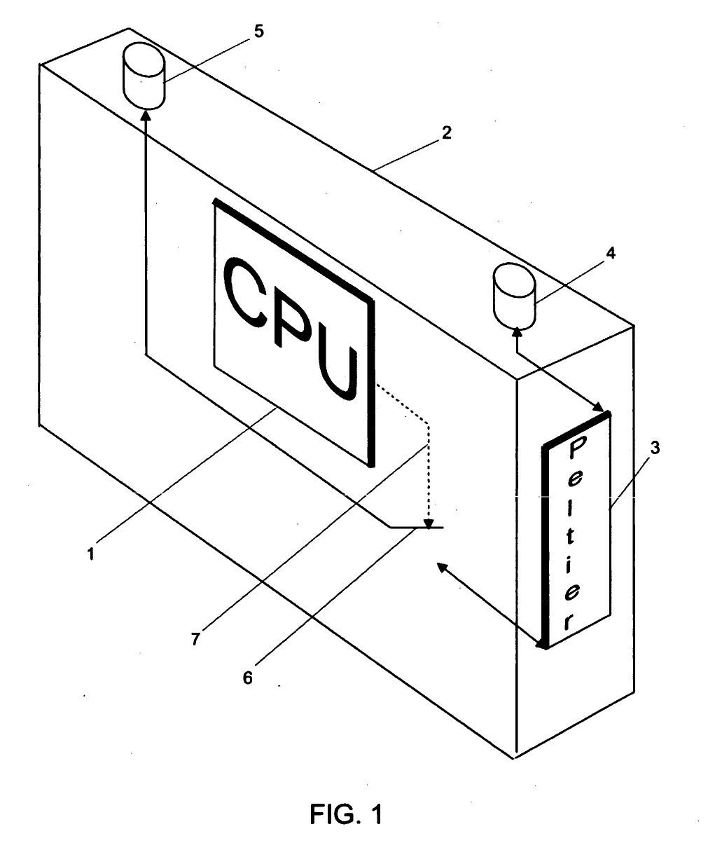

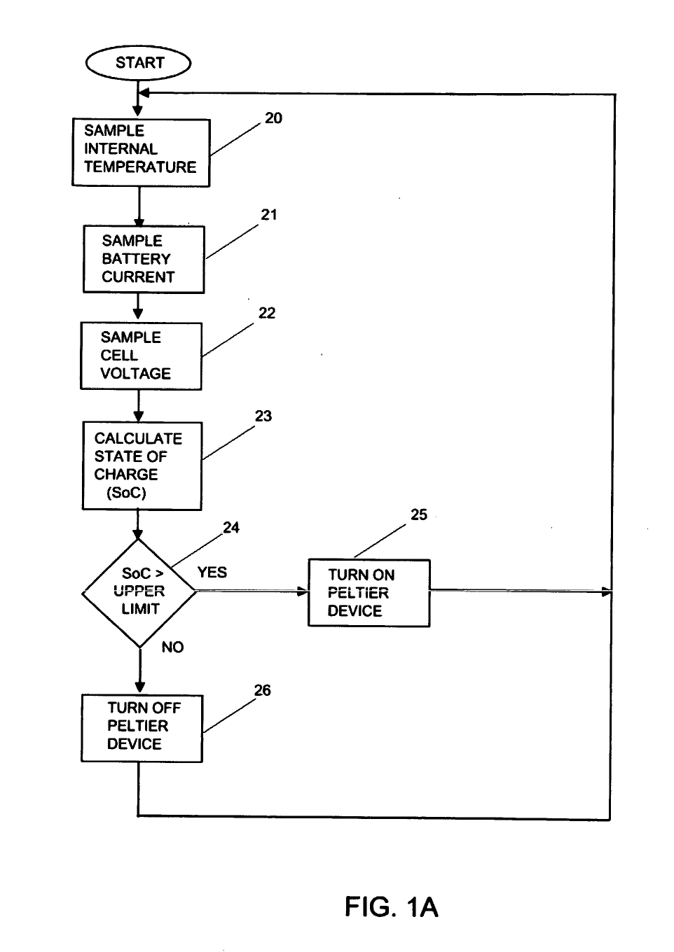

FIG. 1 is a block diagram illustrating central processor unit 1 shown embedded inside battery cell 2. Central processor unit 1 includes a means for switching power from power posts 4 and 5 to the Peltier device 3 by using control signal 7 and electronic switch 6.

FIG. 1A is a flowchart illustrating those steps taken by central processor unit 1 in FIG. 1 in order to calculate the state of charge of the cell and control the operation of the Peltier device based upon the state of charge. In step 20 of FIG. 1A the internal battery temperature is sampled by central processor unit 1 of FIG. 1 and saved. At step 21 of FIG. 1A the cell's current is sampled by central processor unit 1 and saved. At step 22 of FIG. 1A the cell's voltage is sampled by central processor unit 1 of FIG. 1 and saved. At step 23 of FIG. 1A the state of charge of the cell is calculated based upon temperature, current and voltage. At step 24 of FIG. 1A central processor unit 1 of FIG. 1 compares the state of charge against the permissible upper charge limit as stored in central processor unit 1's non-volatile memory. If the permissible upper limit has been exceeded, program control is directed to step 25 where Peltier device 3 of FIG. 1 is switched on using control signal 7 of FIG. 1 to turn on electronic switch 6 of FIG. 1. If the permissible upper limit has not been exceeded, program control is directed to step 26 where Peltier device 3 of FIG. 1 is switched off using control signal 7 of FIG. 1 to turn off electronic switch 6 of FIG. 1. Program control then proceeds to step 20. The flowchart repeats.

In accordance with another embodiment, the present invention makes use of a computer system that resides inside a battery cell and communicates with external devices through an antenna manufactured on or near the surface of the cell's case. A Peltier device is manufactured into the surface of the cell case with one side exposed. The computer system includes temperature, current and voltage sensors. The computer system's central processing unit also has a means to measure time and includes facilities for storing data and program instructions. The computer system's memory includes algorithms that perform cell-balancing by shunting power to the Peltier device when the current passing through the cell is to be moderated. The computer system includes a means for applying either cold or heat to the cell by controlling the polarity of the power applied to the Peltier device. The computer system includes a means to receive new algorithms and operational instructions from external devices.

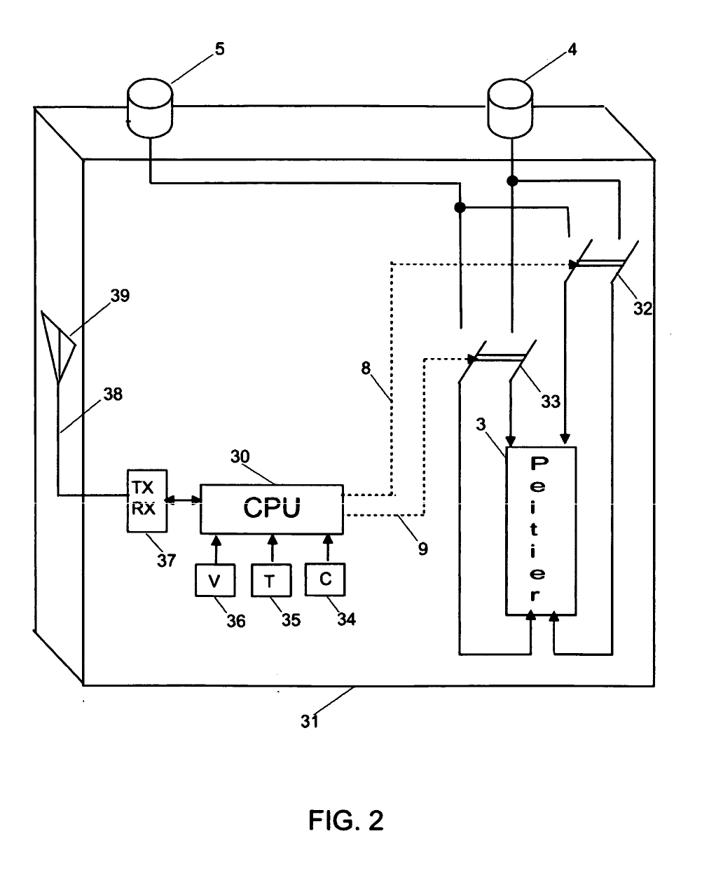

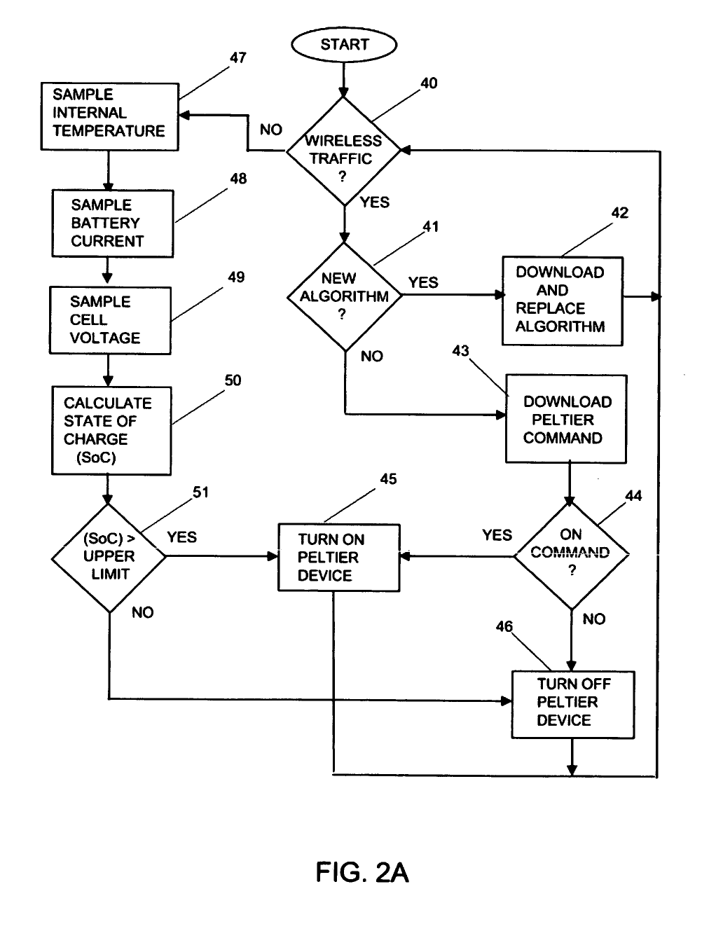

FIG. 2 is a block diagram illustrating central processor unit 30 shown embedded inside battery cell 31. Central processor unit 30 includes a means for switching power from power posts 4 and 5 to the Peltier device 3 by using control signal 8 and electronic switch 32 or control signal 9 and electronic switch 33. Central processor unit 30 includes an electrical connection to antenna 39 through transceiver 37. Transceiver 37 makes use of conductor 38 to transfer digital data over the wireless connection to one or more external devices (not shown). Voltage sensor 36 internally measures the voltage drop between battery cell posts 4 and 5 (the connection between this sensor and the two battery posts not shown). Temperature sensor 35 measures the temperature inside the cell's case. Current sensor 34 measures the current between battery cell posts 4 and 5 (the connection between this sensor and the two battery posts not shown). Central processor unit 30 uses transceiver 37 to monitor wireless traffic that may include command and control information or may contain new cell-balancing algorithms.

FIG. 2A is a flowchart illustrating those steps taken by central processor unit 30 in FIG. 2 in order to perform cell-balancing and shunt the resultant excess energy through the Peltier device in order to either heat or cool the battery cell.

In step 40 of FIG. 2A the data channel in FIG. 2 consisting of antenna 39, conductor 38 and transceiver 37 is monitored for activity. If no data traffic is present program control proceeds to step 47 of FIG. 2A. If data activity is present program control proceeds to step 41 of FIG. 2A where the incoming data is sampled in order to is being downloaded program control proceeds to step 42 of FIG. 2A where the new algorithm is downloaded and replaces the existing cell-balancing algorithm stored in central processor unit 30 of FIG. 2. Program control returns to step 40 of FIG. 2A and the flowchart repeats. If step 41 of FIG. 2A determines that a new algorithm is not being download program control proceeds to step 43 of FIG. 2A where command information is downloaded. At step 44 of FIG. 2A if a command has been received to turn on the Peltier device 3 of FIG. 2, program control proceeds to step 45 of FIG. 2A where the Peltier device 3 of FIG. 2 is turned on. Depending upon the internal temperature of the cell either control signal 8 of FIG. 2 turns on switch 32 of FIG. 2 in order to apply heat to a cold cell or control signal 9 of FIG. 2 turns of switch 33 of FIG. 2 in order to apply cold to a hot cell. Program control then returns to step 40 of FIG. 2A and the flowchart repeats. If at step 44 of FIG. 2A a command has been received to turn off Peltier device 3 of FIG. 2, program control goes to step 46 where both control signal 8 and control signal 9 of FIG. 2 are de-asserted in order to remove all power to Peltier device 3 of FIG. 2. Program control returns to step 40 causing the flow chart to be repeated.

Step 47 of FIG. 2A receives program control from step 40 of FIG. 2A when there is no wireless traffic. In step 47 of FIG. 2A the battery temperature is sampled by central processor unit 30 of FIG. 2 and saved. At step 48 of FIG. 2A the cell's current is sampled by central processor unit 30 and saved. At step 49 of FIG. 2A the cell's voltage is sampled by central processor unit 30 of FIG. 2 and saved. At step 50 of FIG. 2A the state of charge of the cell is calculated based upon temperature, current and voltage. At step 51 of FIG. 2A central processor unit 30 of FIG. 2 compares the state of charge against the permissible upper charge limit as defined by the cell-balancing algorithm. If the permissible upper limit has been exceeded, program control proceeds to step 45 of FIG. 2A where the Peltier device 3 of FIG. 2 is turned on. Depending upon the internal temperature of the cell either control signal 8 of FIG. 2 turns on switch 32 of FIG. 2 in order to apply heat to a cold cell or control signal 9 of then returns to step 40 of FIG. 2A and the flowchart repeats. If the permissible upper limit has not been exceeded, program control goes to step 46 where both control signal 8 and control signal 9 of FIG. 2 are de-asserted in order to remove all power to Peltier device 3 of FIG. 2. Program control returns to step 40. The flow chart repeats.

### Advantage

The advantage of this invention is that it recognizes the synergy that results by manufacturing a Peltier device into the surface of a battery cell, installing the battery management system inside the cell and supplying the normally wasted power, which is a byproduct of cell-balancing, to the Peltier device using no external connections. The polarity of the wasted energy applied to the Peltier device, under the control of the battery management system, will cause the battery cell to either be cooled or heated. By regulating the temperature of the cell with wasted cell-balancing energy the efficiency of the system is improved. By placing the battery management system inside the cell, the temperature of the cell is more accurately monitored, the battery management system's active components become safely encased inside the cell's wall and there are no external connections to the Peltier device. The only external remnant of the battery management system is the wires used for inter-cellular and inter-battery communication. If a wireless communication scheme is adopted even these wires go away and the battery management system disappears from sight.

Manufacturing costs are driven down because the battery management system is integrated within the cell, cell efficiency is driven up because the Peltier device moderates the cell's temperature with free energy and the physical integrity of the system is improved since the battery management system safely resides inside the cell's walls.

What is claimed is:

1. A Peltier device manufactured into the surface of a battery cell.

2. The Peltier device of claim 1 whereby its energy source comes from the battery cell.

3. The energy source of claim 2 consists of the excess energy that is a byproduct resulting from the cell-balancing operation performed by a battery management system.

4. The battery management system of claim 3 is manufactured inside the vehicular battery cell.

5. The battery cell of claim 4 is a lithium-based cell.
